(19) United States
(12) Patent Application Publication
(10) Pub. No.: US 2025/0079264 A1
(43) Pub. Date: Mar. 6, 2025

(54) SEMICONDUCTOR POWER MODULE

(71) Applicant: ZF Friedrichshafen AG, Friedrichshafen (DE)

(72) Inventors: Shaozhi Yuan, Shanghai (CN); Qing Xu, Shanghai (CN)

(73) Assignee: ZF Friedrichshafen AG, Friedrichshafen (DE)

(21) Appl. No.: 18/816,204

(22) Filed: Aug. 27, 2024

(30) Foreign Application Priority Data
Aug. 29, 2023 (CN) 202311100380.1

(51) Int. Cl. H01L 23/473; H01L 23/24; H01L 23/367; H01L 23/52; H01L 25/065

(52) U.S. Cl. CPC H01L 23/473; H01L 23/3677; H01L 25/0655; H01L 23/24; H01L 23/52

(57) ABSTRACT

A semiconductor power module including a plurality of inverter units, each including power chips, an AC terminal, a DC positive terminal, and a DC negative terminal, an upper surface of the AC terminal being connected to the power chips and having first heat dissipation columns arranged on a lower surface, an upper surface of the DC positive terminal being connected to the power chips and having a second heat dissipation columns arranged on a lower surface; and a liquid tank having a groove for containing a coolant. The AC terminal and DC positive terminal lower surfaces face the groove, the first and second heat dissipation columns extending into the groove, and the coolant being an insulating liquid. Heat from the semiconductor power module is not transferred through the insulating layer, but is directly transferred to the coolant through the terminals, which provides an advantage of high heat dissipation efficiency.

### CROSS-REFERENCE TO RELATED APPLICATION

This application claims priority to China Application No. 202311100380.1, filed on Aug. 29, 2023, the entirety of which is hereby fully incorporated by reference herein.

### TECHNICAL FIELD

The present application mainly relates to the field of semiconductor device packaging, and in particular to a semiconductor power module.

### BACKGROUND

The semiconductor power module is one of core components of a drive device in a new energy vehicle. The power of a single power chip is relatively low, and the semiconductor power module usually adopts a plurality of power chips in parallel to increase the power density. The plurality of power chips will produce a lot of heat after long-time operation. If the heat is not dissipated in time and effectively, the normal operation of the semiconductor power module will be affected, or even the semiconductor power module may be damaged.

In the existing water-cooling solution, an insulating layer is arranged between a water-cooling device and the power chips, and the heat produced by the power chips is transferred to the water-cooling device through the insulating layer. As the switching rate of the power chips is getting faster and faster, they produce significantly more heat than the previous low-power chips. In addition, as the size of the power chips is getting smaller and smaller, the number of power chips arranged per unit area gradually rises, thus the requirements for heat dissipation per unit area are also getting higher.

### SUMMARY

The technical problem to be solved in the present application is to provide a semiconductor power module, which can dissipate heat from power chips in a timely and effective manner.

The technical solution adopted in the present application to solve the above technical problem is a semiconductor power module, including: a plurality of inverter units, each of which comprises a plurality of power chips, an AC terminal, a DC positive terminal and a DC negative terminal, an upper surface of the AC terminal being connected to the plurality of power chips, the AC terminal having a plurality of first heat dissipation columns arranged on a lower surface, an upper surface of the DC positive terminal being connected to the plurality of power chips, and the DC positive terminal having a plurality of second heat dissipation columns arranged on a lower surface; and a liquid tank having a groove for containing a coolant, the lower surface of the AC terminal facing the groove, the first heat dissipation columns extending into the groove, the lower surface of the DC positive terminal facing the groove, the second heat dissipation columns extending into the groove, and the coolant being an insulating liquid.

In an embodiment of the present application, the groove includes a first sub-groove and a second sub-groove adjacent to each other, the lower surface of the AC terminal faces the first sub-groove, the first heat dissipation columns extend into the first sub-groove, the lower surface of the DC positive terminal faces the second sub-groove, and the second heat dissipation columns extend into the second sub-groove.

In an embodiment of the present application, the first sub-groove has a first liquid inlet and a first liquid outlet, the second sub-groove has a second liquid inlet and a second liquid outlet, and the coolant enters the grooves from the liquid inlets and is drained out of the grooves from the liquid outlets.

In an embodiment of the present application, the plurality of power chips are arranged to form a first row of power chips and a second row of power chips, and the first row of power chips and the second row of power chips are arranged adjacent to each other.

In an embodiment of the present application, the upper surface of the AC terminal is connected to drains of the first row of power chips and sources of the second row of power chips.

In an embodiment of the present application, the upper surface of the DC positive terminal is connected to drains of the second row of power chips, and an upper surface of the DC negative terminal is connected to sources of the first row of power chips.

In an embodiment of the present application, the groove further includes a third sub-groove, the first sub-groove is arranged between the second sub-groove and the third sub-groove, and a lower surface of the DC negative terminal faces the third sub-groove.

In an embodiment of the present application, the AC terminal, the DC positive terminal and the DC negative terminal are all made of metal copper.

In an embodiment of the present application, the power module further includes several sealing rings, each of the sealing rings being arranged between a corresponding inverter unit and the groove to seal the groove.

In another aspect of the present application, a motor controller is further proposed, including the power module described above.

The heat of the semiconductor power module of the present application is not transferred in a path passing through the insulating layer, but is directly transferred to the coolant through the terminals, which has the advantage of a high heat dissipation efficiency.

### BRIEF DESCRIPTION OF THE DRAWINGS

FIG. 1 is a schematic perspective view of a semiconductor power module according to an embodiment of the present application;

FIG. 2A is a schematic perspective view of a semiconductor power module according to another embodiment of the present application;

FIG. 2B is a top view of the semiconductor power module in FIG. 2A;

FIG. 2C is a schematic sectional view of the semiconductor power module in FIG. 2B along line A-A;

FIG. 2D is a schematic partial enlarged view of circle B in FIG. 20;

FIGS. 3A and 3B are schematic perspective views of an inverter unit according to an embodiment of the present application;

FIG. 3C is a schematic top view of the inverter unit in FIG. 3A;

FIG. 3D is a schematic bottom view of the inverter unit in FIG. 3A; and

FIG. 3E is a schematic front view of the inverter unit in FIG. 3A.

### DETAILED DESCRIPTION

In order to make the above-mentioned objectives, features, and advantages of the present application more obvious and easy to understand, the specific implementations of the present application are described in detail below with reference to the accompanying drawings.

In the following description, many specific details are set forth to fully understand the present application, but the present application may also be implemented in other manners different from those described herein, and therefore the present application is not limited to the specific embodiments disclosed below.

As shown in the present application and the embodiments, unless the context expressly indicates otherwise, the words “a”, “an”, “said”, and/or “the” do not specifically refer to the singular, but may also include the plural. Generally, the terms “include” and “comprise” only suggest that the expressly identified steps and elements are included, but these steps and elements do not constitute an exclusive list, and the method or device may further include other steps or elements.

Furthermore, it should be noted that, the use of terms such as “first” and “second” to define parts is merely for ease of facilitating differentiation of the corresponding parts. If not otherwise stated, the above terms have no special meanings and thus cannot be construed as limiting the scope of protection of the present application. Furthermore, although the terms used in the present application are selected from well-known common terms, some of the terms mentioned in the description of the present application may have been selected by the applicant according to his or her determination, and the detailed meaning thereof is described in the relevant section described herein. Furthermore, the present application must be understood, not simply by the actual terms used but also by the meanings encompassed by each term.

The semiconductor power module of the present application will be described below with reference to specific embodiments.

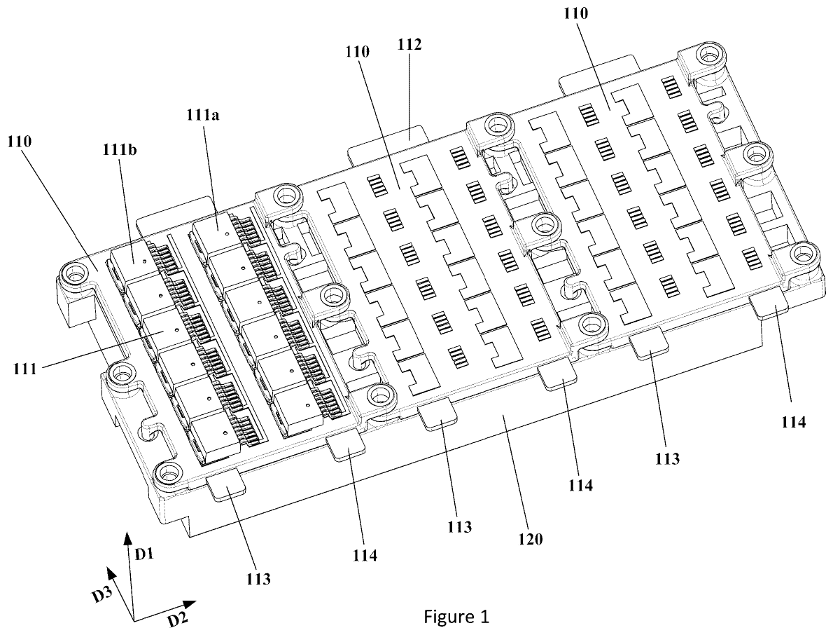

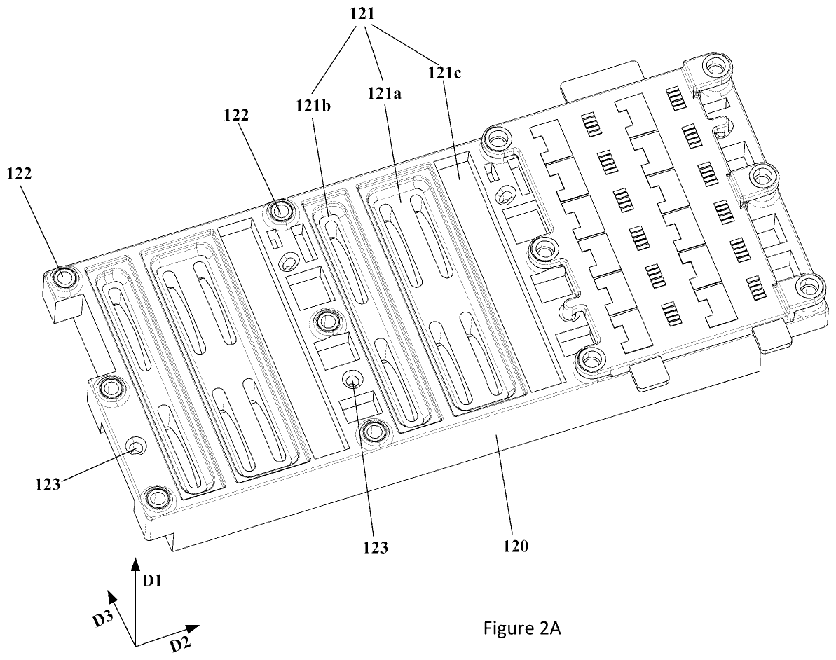

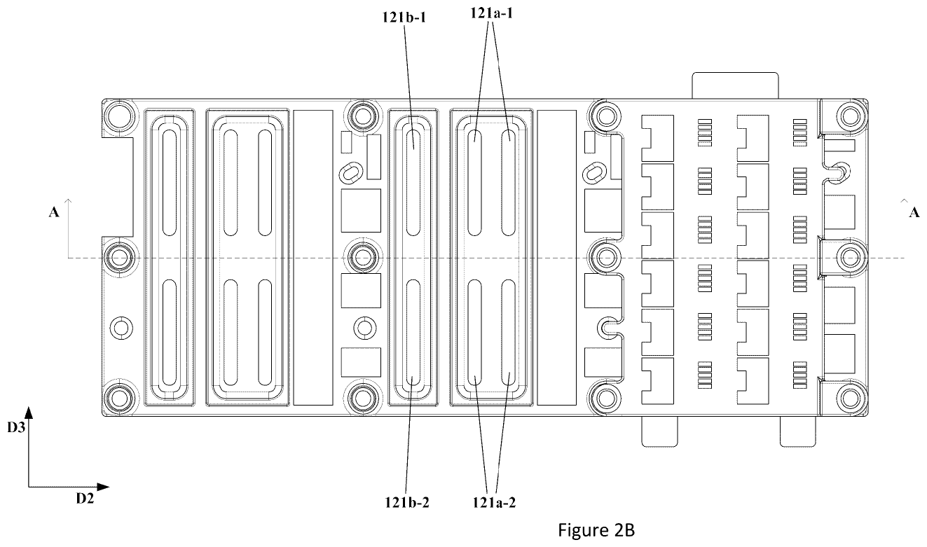

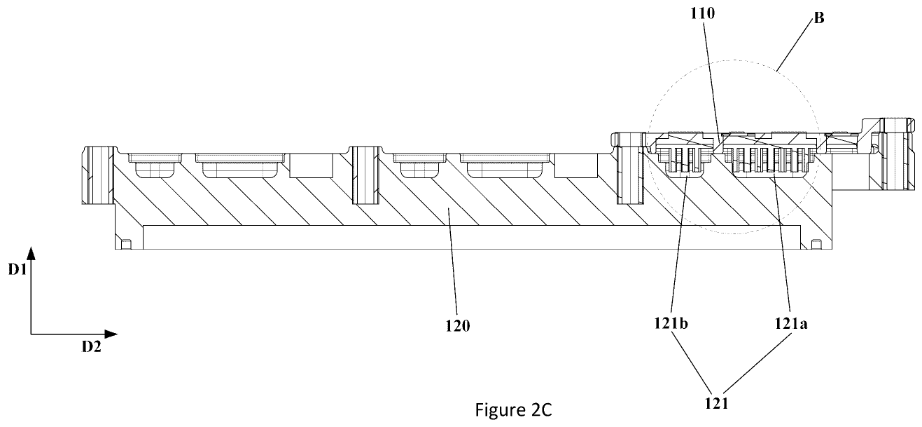

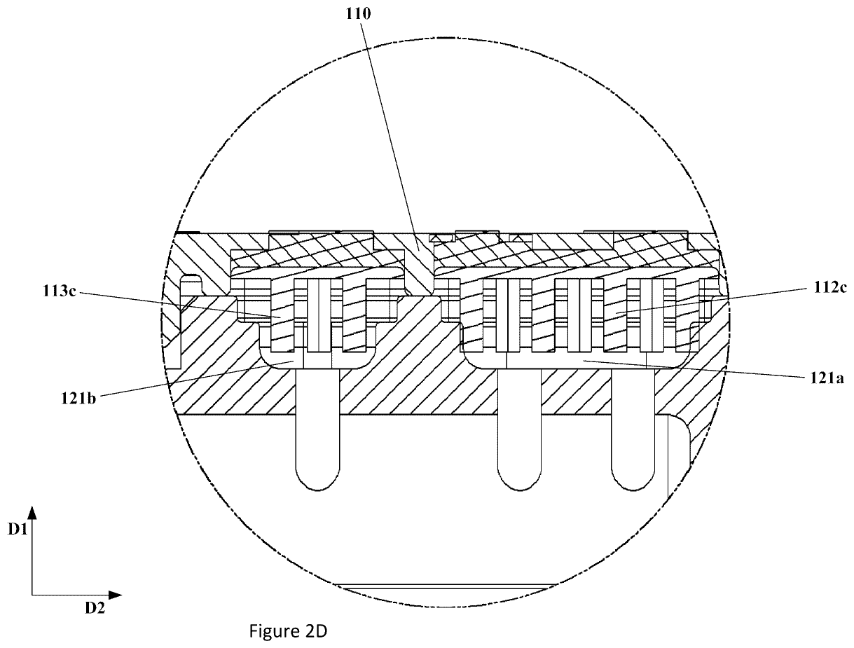

FIG. 1 is a schematic perspective view of a semiconductor power module according to an embodiment, FIG. 2A is a schematic perspective view of a semiconductor power module according to another embodiment, FIG. 2B is a top view of the semiconductor power module in FIG. 2A, FIG. 2C is a schematic sectional view of the semiconductor power module in FIG. 2B along line A-A, and FIG. 2D is a schematic partial enlarged view of circle B in FIG. 2C. With reference to FIGS. 1 to 2D, the semiconductor power module includes three inverter units 110 and a liquid tank 120. The three inverter units 110 are arranged above the liquid tank 120 in a first direction D1 and adjacent to each other in a second direction D2. The three inverter units 110 can form three phases U, V and W, which are configured to convert a direct current into a three-phase alternating current. In some embodiments, there may be two inverter units 110.

As shown in FIG. 1, each inverter unit 110 includes a plurality of power chips 111, an AC terminal 112, a DC positive terminal 113, and a DC negative terminal 114. In FIG. 1, for the sake of simplicity, the power chips of the two inverter units 110 on the right are omitted. In FIG. 1, the plurality of power chips 110 are arranged to form a first row of power chips 111a and a second row of power chips 111b. The first row of power chips 111a and the second row of power chips 111b are arranged adjacent to each other in the second direction D2. Each row includes six power chips 111 arranged adjacent to each other in a third direction D3. The number of the power chips 111 of each inverter unit 110 is not limited to 12 as shown in FIG. 1, and the number of the power chips 111 may be changed according to needs. The power chip 111 in the present application may be selected from a silicon carbide-based metal oxide semiconductor field effect transistor (SiCMOSFET), a silicon-based metal oxide semiconductor field effect transistor (SiMOSFET), a gallium nitride high electron mobility transistor (GaNHEMT), or an insulated gate bipolar transistor (IGBT).

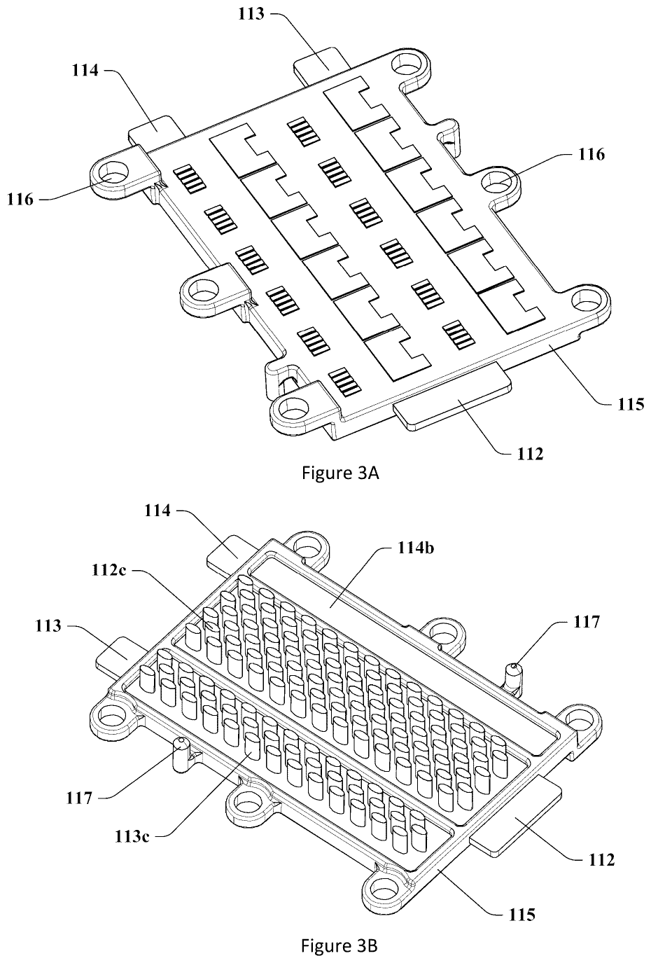

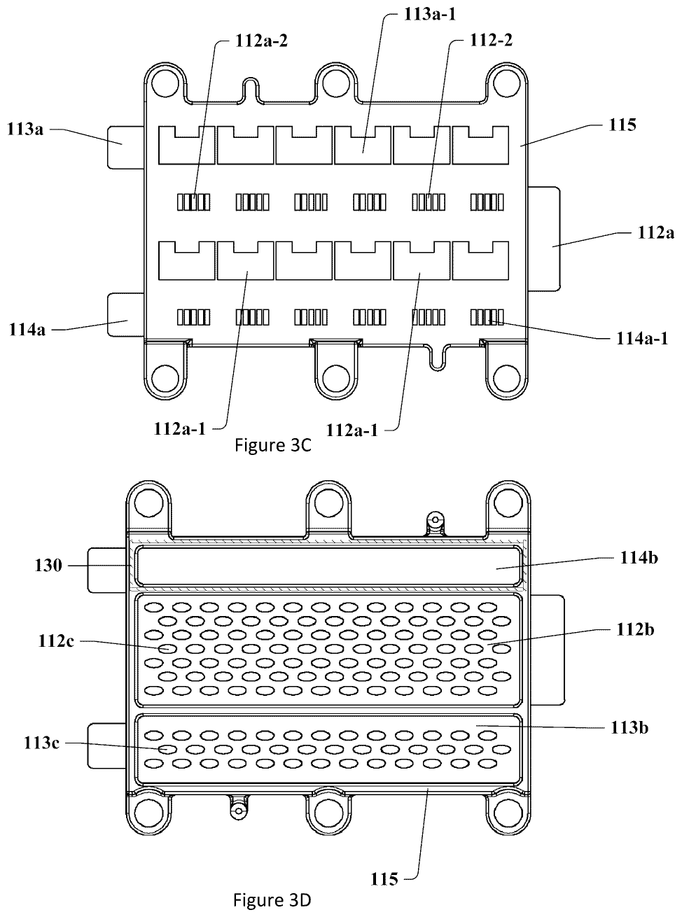

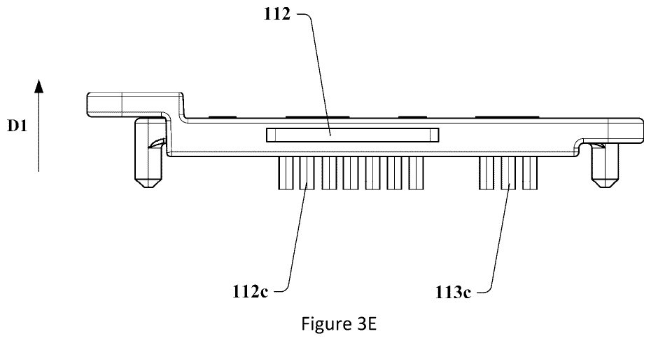

FIGS. 3A and 3B are schematic perspective views of an inverter unit according to an embodiment, FIG. 3C is a schematic top view of the inverter unit in FIG. 3A, FIG. 3D is a schematic bottom view of the inverter unit in FIG. 3A, and FIG. 3E is a schematic front view of the inverter unit in FIG. 3A. With reference to FIGS. 3A to 3E, the AC terminal 112 has an upper surface 112a and a lower surface 112b opposite to each other. With reference to FIGS. 1 and 3A to 3E, the upper surface 112a of the AC terminal 112 is connected to drains of the first row of power chips 111a, and the upper surface 112a is further connected to sources of the second row of power chips 111b. With reference to FIG. 3C, the upper surface 112a can be connected to the drains of the first row of power chips 111a through drain pads 112a-1 and to the sources of the second row of power chips 111b through source pads 112a-2. As such, the AC terminal 112 can establish electrical connections with the power chips 111.

As shown in FIGS. 3C and 3D, the DC positive terminal has an upper surface 113a and a lower surface 113b opposite to each other. The DC negative terminal has an upper surface 114a and a lower surface 114b opposite to each other. As shown in FIG. 1, the upper surface 113a of the DC positive terminal is connected to drains of the second row of power chips 111b. The upper surface 113a may be connected to the drains of the second row of power chips 111b through drain pads 113a-1. The upper surface 114a of the DC negative terminal is connected to sources of the first row of power chips 111a. The upper surface 114a may be connected to the sources of the first row of power chips 111a through source pads 114a-1. As such, the DC positive terminal 113 and the DC negative terminal 114 can establish electrical connections with the power chips, respectively.

With reference to FIGS. 3A to 3D, the inverter unit 110 includes a shell 115. The shell 115 covers part of the upper surface 112a of the AC terminal 112, part of the upper surface 113a of the DC positive terminal 113, and part of the upper surface 114a of the DC negative terminal 114, thus only part of the upper surface of each terminal can be seen in FIG. 3C. In some embodiments, the shell 115 and the terminals may be formed by using an insert casting process.

With reference to FIGS. 3B to 3E, the AC terminal 112 has a plurality of first heat dissipation columns 112c arranged on the lower surface 112b. One end of the first heat dissipation column 112c is connected to the lower surface 112b, and the other end extends downward in the first direction D1. The AC terminal 112 and the first heat dissipation columns 112c may be integrally formed. For example, the AC terminal 112 and the first heat dissipation columns 112c may be integrally formed by using a casting process. As shown in FIG. 3D, the plurality of first heat dissipation columns 112c are distributed on the lower surface 112b. Two adjacent first heat dissipation columns 112c are spaced apart by a certain distance, which is beneficial to heat exchange between the first heat dissipation columns 112c and a coolant. The present application does not limit the number, the cross-sectional shape and the arrangement of the first heat dissipation columns 112c.

Similar to the first heat dissipation columns 112c of the AC terminal 112, the DC positive terminal 113 has a plurality of second heat dissipation columns 113c arranged on the lower surface 113b. As shown in FIGS. 3D and 3E, one end of the second heat dissipation column 113c is connected to the lower surface 113b, and the other end thereof extends downward in the first direction D1. The DC positive terminal 113 and the second heat dissipation columns 113c may be integrally formed. As shown in FIG. 3D, the plurality of second heat dissipation columns 113c are distributed on the lower surface 113b. Two adjacent second heat dissipation columns 113c are spaced by a certain distance, which is beneficial to heat exchange between the second heat dissipation columns 113c and the coolant. The present application does not limit the number, the cross-sectional shape and the arrangement of the second heat dissipation columns 113c.

With reference to FIGS. 2A and 2C, the liquid tank 120 has a groove 121, which may be configured to contain the coolant. The groove 121 may be further divided into a first sub-groove 121a and a second sub-groove 121b. The first sub-groove 121a and the second sub-groove 121b are adjacently distributed in the second direction D2 and have a certain depth in the first direction D1. Each groove has an opening facing upward in the first direction D1.

As shown in FIGS. 1 and 2C, the liquid tank 120 has three grooves 121 adjacently distributed in the second direction D2, and each groove 121 covers a corresponding inverter unit 110. The groove 121 may be configured to contain the coolant, and the heat dissipation columns of the terminal may extend into a corresponding groove, so as to perform heat exchange with the coolant in the groove to dissipate heat for the power chips, which is specifically described as follows.

With reference to FIGS. 2C, 2D and 3D, the inverter unit 110 covers the groove 121, the lower surface 112b of the AC terminal 112 faces the first sub-groove 121a, and the first heat dissipation columns 112c extend into the first sub-groove 121a. The lower surface 113b of the DC positive terminal 113 faces the second sub-groove 121b, and the second heat dissipation columns 113c extend into the second sub-groove 121b. The heat dissipation columns extending into the groove are in direct contact with the coolant in the groove. Since the heat dissipation columns are part of the terminal, the heat produced by the power chips and the heat produced by the terminal can be directly transferred to the heat dissipation columns, and the heat dissipation columns directly transfer the heat to the coolant in contact with the heat dissipation columns. In some embodiments, in order to improve the conductivity and heat dissipation performance of the terminals, the AC terminal, the DC positive terminal and the DC negative terminal are all made of metal copper.

In the existing water-cooling solution, an insulating layer (or other material layers, such as a thermal interface material layer) is provided between a heat dissipation device and the power chips (or terminals), and the terminals are not in direct contact with the coolant. In the present application, no insulating layer is provided between the liquid tank and the power chips, and the heat produced by the power chips is directly transferred to the coolant through the terminals, which has the advantage of a high heat dissipation efficiency. In other words, a heat transfer path in the present application is: power chip-terminal-coolant, and the heat transfer path in the prior art is: power chip-terminal-insulating layer-coolant. Therefore, the present application has the advantages of a short heat transfer path and a high heat dissipation efficiency. Furthermore, the present application also omits the insulating layer or the thermal interface material layer.

In the prior art, the tank for containing the coolant is made of metal and has no other openings other than a coolant inlet and outlet. The liquid tank 120 in the present application is made of plastic and has an open opening in addition to the coolant inlet and outlet, thus the liquid tank 120 has the advantage of low costs.

The coolant in the groove is an insulating liquid. When the semiconductor power module works, the heat dissipation columns connected to the terminal is charged. Since the coolant is non-conductive, the charged heat dissipation columns will not affect other electrical units in the semiconductor power module.

With reference to FIGS. 2A and 2B, in an embodiment, the first sub-groove 121a has a first liquid inlet 121a-1 and a first liquid outlet 121a-2. The first liquid inlet 121a-1 and the first liquid outlet 121a-2 are both provided at the bottom of the first sub-groove 121a. The coolant can be provided to the first sub-groove 121a through the first liquid inlet 121a-1, and the coolant in the first sub-groove 121a can be drained through the first liquid outlet 121a-2, so that the coolant is in a flowing state in the first sub-groove 121a.

Likewise, the second sub-groove 121b has a second liquid inlet 121b-1 and a second liquid outlet 121b-2. The second liquid inlet 121b-1 and the second liquid outlet 121b-2 are both provided at the bottom of the second sub-groove 121b. The coolant can be provided to the first sub-groove 121a through the second liquid inlet 121b-1, and the coolant in the first sub-groove 121a can be drained through the second liquid outlet 121b-2, so that the coolant is in a flowing state in the second sub-groove 121b.

With reference to FIG. 2A, in some embodiments, the groove 121 further includes a third sub-groove 121c. The first sub-groove 121a is located between the second sub-groove 121b and the third sub-groove 121c in the second direction D2. As shown in FIGS. 1, 2A and 3B, the lower surface 114a of the DC negative terminal 114 faces the third sub-groove 121c. The reason why no heat dissipation column is provided on the lower surface 114a of the DC negative terminal 114 is as follows. The DC negative terminal 114 is connected to the sources of the power chips 111, and the heat transferred from the power chips to the DC negative terminal 114 and the heat produced by the DC negative terminal 114 itself are small. Of course, heat dissipation columns similar to that of the AC terminal may also be provided on the lower surface 114a of the DC negative terminal 114.

With reference to FIGS. 3B and 3D, in an embodiment, the power module further includes three sealing rings (not shown). The three sealing rings are arranged around the AC terminal 112, the DC positive terminal 113 and the DC negative terminal 114 respectively, and are close to the lower surfaces of the corresponding terminals. For ease of understanding, the sealing ring 130 around the DC negative terminal 114 is shown in FIG. 3D. As shown in FIG. 1, after the inverter units 110 and the liquid tank 120 are coupled, each sealing ring is arranged between the corresponding inverter unit 110 and the groove in the first direction D1, so as to seal the groove.

With reference to FIGS. 2A, 3A and 3B, the way in which the inverter units 110 and the liquid tank 120 are coupled will be described below. As shown in FIG. 2A, a row of first mounting holes 122 are distributed on each of opposite sides of each groove 121 in the liquid tank 120, and adjacent grooves 121 share one row of first mounting holes 122, which is beneficial to reducing the volume of the power module and lowering the cost of processing the mounting holes. Positioning holes 123 are also distributed on the opposite sides of each groove 121. As shown in FIG. 3A, a row of second mounting holes 116 are distributed on each of opposite sides of each inverter unit 110. As shown in FIG. 3B, positioning pins 117 are distributed on the opposite sides of each inverter unit 110 respectively. As shown in FIGS. 2A, 3A and 3B, the positioning pins 117 of each inverter unit 110 are inserted into the corresponding positioning holes 123. After the inverter unit 110 is positioned, the first mounting hole 122 is aligned with the corresponding second mounting hole 116. Then, the first mounting hole 122 and the corresponding second mounting hole 116 can be connected by means of a bolt or other connector, thereby realizing the coupling between the inverter unit 110 and the liquid tank 120. It should be understood that the coupling method between the inverter unit 110 and the liquid tank 120 is not limited to the above embodiment.

In another aspect of the present application, a motor controller is further proposed, which includes the power module mentioned above. The motor controller has the advantages of a high heat dissipation efficiency and a low heat dissipation cost.

The basic concepts have been described above. For those skilled in the art, the above disclosure of the present application is merely used as an example and does not constitute a limitation on the present application. Although not explicitly stated herein, various modifications, improvements and amendments may be made to the present application by those skilled in the art. Such modifications, improvements and amendments are suggested in the present application, and therefore, such modifications, improvements and amendments still fall within the spirit and scope of the exemplary embodiments of the present application.

Meanwhile, the present application uses specific terms to describe the embodiments of the present application. For example, “one embodiment”, “an embodiment”, and/or “some embodiments” mean a feature, structure, or characteristic associated with at least one embodiment of the present application. Therefore, it should be emphasized and noted that two or more references to “an embodiment” or “one embodiment” or “an alternative embodiment” in various places in this specification do not necessarily indicate the same embodiment. Furthermore, some features, structures, or characteristics of the one or more embodiments of the present application may be combined appropriately.

Figures for describing the quantity of components and attributes are used in some embodiments. It should be understood that such figures for use in the description of the embodiments are modified with modifiers “about,” “approximately,” or “substantially” in some examples. Unless otherwise stated, “about”, “approximately”, or “substantially” indicates that the stated number allows for a variation of ±20%. Accordingly, in some embodiments, numerical parameters used in the description and the embodiments are all approximations, which can change depending on desired characteristics of individual embodiments. In some embodiments, for the numerical parameters, a specified number of valid digits should be considered, and a general bit retention method is used. Although numerical fields and parameters used to confirm the breadth of their ranges in some embodiments of the present application are approximations, such values are set to the extent practicable as precisely as possible in specific embodiments.

### LIST OF REFERENCE NUMERALS

inverter unit 110
power chip 111
first row of power chips 111a
second row of power chips 111b
AC terminal 112
upper surface 112a
lower surface 112b
first heat dissipation column 112c
DC positive terminal 113
upper surface 113a
lower surface 113b
second heat dissipation column 113c
DC negative terminal 114
upper surface 114a
lower surface 114b
shell 115
second mounting hole 116
positioning pin 117
liquid tank 120
groove 121
first sub-groove 121a
first liquid inlet 121a-1
first liquid outlet 121a-2
second sub-groove 121b
second liquid inlet 121b-1
second liquid outlet 121b-2
third sub-groove 121c
first mounting hole 122
positioning hole 123
sealing ring 130

1. A semiconductor power module, comprising:
a plurality of inverter units, each of which comprises a plurality of power chips, an AC terminal, a DC positive terminal, and a DC negative terminal, an upper surface of the AC terminal being connected to the plurality of power chips, the AC terminal having a plurality of first heat dissipation columns arranged on a lower surface, an upper surface of the DC positive terminal being connected to the plurality of power chips, and the DC positive terminal having a plurality of second heat dissipation columns arranged on a lower surface; and
a liquid tank having a groove for containing a coolant, the lower surface of the AC terminal facing the groove, the first heat dissipation columns extending into the groove, the lower surface of the DC positive terminal facing the groove, the second heat dissipation columns extending into the groove, and the coolant being an insulating liquid.

2. The power module of claim 1,
wherein the groove comprises a first sub-groove and a second sub-groove adjacent to each other,
wherein the lower surface of the AC terminal faces the first sub-groove, the first heat dissipation columns extend into the first sub-groove, the lower surface of the DC positive terminal faces the second sub-groove, and the second heat dissipation columns extend into the second sub-groove.

3. The power module of claim 2,
wherein the first sub-groove has a first liquid inlet and a first liquid outlet, the second sub-groove has a second liquid inlet and a second liquid outlet, and the coolant enters the grooves from the liquid inlets and is drained out of the grooves from the liquid outlets.

4. The power module of claim 1,
wherein the plurality of power chips are arranged to form a first row of power chips and a second row of power chips, and the first row of power chips and the second row of power chips are arranged adjacent to each other.

5. The power module of claim 4,
wherein the upper surface of the AC terminal is connected to drains of the first row of power chips and sources of the second row of power chips.

6. The power module of claim 5,
wherein the upper surface of the DC positive terminal is connected to drains of the second row of power chips, and an upper surface of the DC negative terminal is connected to sources of the first row of power chips.

7. The power module of claim 2,
wherein the groove further comprises a third sub-groove, the first sub-groove is arranged between the second sub-groove and the third sub-groove, and a lower surface of the DC negative terminal faces the third sub-groove.

8. The power module of claim 1,
wherein the AC terminal, the DC positive terminal, and the DC negative terminal are all made of metal copper.

9. The power module of claim 1, further comprising:
a plurality of sealing rings, each of the sealing rings being arranged between a corresponding inverter unit and the groove to seal the groove.

10. A motor controller, comprising:
the power module of claim 1.
